(19) United States
(12) Patent Application Publication
(10) Pub. No.: US 2025/0022843 A1
(43) Pub. Date: Jan. 16, 2025

(54) SEMICONDUCTOR PACKAGE AND METHOD FOR MANUFACTURING THE SAME

(71) Applicant: SAMSUNG ELECTRONICS CO., LTD., Gyeonggi-do (KR)

(72) Inventors: Hyunsoo Chung, Suwon-si (KR); Jaesic Lee, Suwon-si (KR); Inhyo Hwang, Suwon-si (KR)

(73) Assignee: SAMSUNG ELECTRONICS CO., LTD., Gyeonggi-do (KR)

(21) Appl. No.: 18/428,633

(22) Filed: Jan. 31, 2024

(30) Foreign Application Priority Data
Jul. 13, 2023 (KR) 10-2023-0091376

(51) Int. Cl. H01L 25/065; H01L 23/00; H01L 23/29; H01L 23/31; H01L 23/367; H01L 23/373; H01L 25/00; H01L 25/18

(52) U.S. Cl. CPC H01L 25/0652; H01L 23/29; H01L 23/31; H01L 23/367; H01L 23/3738; H01L 24/08; H01L 24/80; H01L 25/18; H01L 25/50; H01L 2224/08235; H01L 2224/80011; H01L 2924/1433; H01L 2924/181

(57) ABSTRACT

Provided a semiconductor package including a redistribution structure, a semiconductor structure on the redistribution structure, a plurality of semiconductor stacking structures on the redistribution structure, the plurality of semiconductor stacking structures being adjacent to the semiconductor structure, and a height of each of the plurality of semiconductor stacking structures being greater than a height of the semiconductor structure, and a heat dissipation structure on the semiconductor structure, the heat dissipation structure including a plurality of through openings, wherein each semiconductor stacking structure among the plurality of semiconductor stacking structures is positioned within a corresponding through opening among the plurality of through openings, and wherein an upper surface of each of the plurality of semiconductor stacking structures is exposed through the corresponding through opening.

### CROSS-REFERENCE TO RELATED APPLICATION

This application claims priority to Korean Patent Application No. 10-2023-0091376 filed in the Korean Intellectual Property Office on Jul. 13, 2023, the disclosure of which is incorporated herein in its entirety by reference.

### BACKGROUND

### 1. Field

Embodiments of the present disclosure relate to a semiconductor package and a manufacturing method thereof.

### 2. Description of Related Art

A semiconductor industry field is seeking to improve an integration density to integrate a greater number of passive or active devices in a given region. Among them, a development of a technology for miniaturizing a circuit line width of a front end process of the semiconductor gradually faced limitations, accordingly, the semiconductor industry field is trending to supplement the limitations of the front end process of the semiconductor by developing a semiconductor package technology that can have a high integration density. One of the semiconductor package technologies developed is a 2.5D package technology in which a logic die and a high bandwidth memory (HBM) on a silicon interposer are disposed to operate as a single semiconductor. This 2.5D package is completed through processes of molding the logic die and the HBM disposed on the silicon interposer with a molding material, mounting the silicon interposer on a printed circuit board (PCB), and filling the space between the printed circuit board and the silicon interposers with an underfill material.

Here, since the HBM is formed by vertically stacking individual memory dies, it has a greater height than the logic die. Therefore, the 2.5D package has a structural characteristic in which the upper surface of the HBM is exposed from the molding material and the upper surface of the logic die having the relatively low-height is molded by the molding material, and thus, it may be difficult to effectively dissipate heat generated in the logic die to the outside of the 2.5D package.

In addition, since the logic die and the HBM are disposed side by side on the silicon interposer, the 2.5D package has a wide area in the horizontal direction, and a bending may occur in the underfill material covering this large area, thereby causing cracks at the boundary between the molding material and the silicon interposer.

Therefore, it is necessary to develop a new package technology that may solve the problem of the 2.5D package described above.

### SUMMARY

According to an aspect of an embodiment, there is provided a semiconductor package including a redistribution structure, a semiconductor structure on the redistribution structure, a plurality of semiconductor stacking structures on the redistribution structure, the plurality of semiconductor stacking structures being adjacent to the semiconductor structure, and a height of each of the plurality of semiconductor stacking structures being greater than a height of the semiconductor structure, and a heat dissipation structure on the semiconductor structure, the heat dissipation structure including a plurality of through openings, wherein each semiconductor stacking structure among the plurality of semiconductor stacking structures is positioned within a corresponding through opening among the plurality of through openings, and wherein an upper surface of each of the plurality of semiconductor stacking structures is exposed through the corresponding through opening.

According to another aspect of an embodiment, there is provided a semiconductor package including a substrate, a redistribution structure on the substrate, a plurality of conductive posts on the redistribution structure, a bridge die on the redistribution structure, a first molding material molding the plurality of conductive posts and the bridge die on the redistribution structure, a semiconductor structure on the first molding material, a plurality of semiconductor stacking structures on the first molding material, the plurality of semiconductor stacking structures being adjacent to the semiconductor structure, and a height each of the plurality of semiconductor stacking structures being greater than a height of the semiconductor structure, a heat dissipation structure on the semiconductor structure, the heat dissipation structure including a plurality of through openings, and each of the plurality of semiconductor stacking structures being positioned within a corresponding through opening of the plurality of through openings, and an upper surface of each of the plurality of semiconductor stacking structures being exposed through the corresponding through opening, and a second molding material, that molds the semiconductor structure and the plurality of semiconductor stacking structures, between the first molding material and the heat dissipation structure.

According to another aspect of an embodiment, there is provided a manufacturing method of a semiconductor package including forming a plurality of cavities on a first surface of a carrier, forming a plurality of semiconductor stacking structures and a semiconductor structure on the carrier, each semiconductor stacking structure among the plurality of semiconductor stacking structures being formed within a corresponding cavity among the plurality of cavities, the semiconductor structure being formed on the first surface of the carrier between the plurality of cavities, and a height of each of the plurality of semiconductor stacking structures being higher than a height of the semiconductor structure, molding the plurality of semiconductor stacking structures and the semiconductor structure with a molding material on the carrier, forming a redistribution structure on the molding material, and planarizing a second surface of the carrier opposite to the first surface of the carrier to expose an upper surface of each of the plurality of semiconductor stacking structures.

### BRIEF DESCRIPTION OF DRAWINGS

The above and other aspects, features, and advantages of example embodiments of the disclosure will be more apparent from the following description taken in conjunction with the accompanying drawings, in which:

FIG. 1 is a cross-sectional view showing a semiconductor package of an embodiment;

FIG. 2 is a top plan view showing an upper surface of a semiconductor package of FIG. 1; and

FIGS. 3, 4, 5, 6, 7, 8, 9, 10, 11, 12, 13, 14, 15, 16, 17, 18, and 19 are cross-sectional views showing a method of manufacturing of a semiconductor package of an embodiment.

### DETAILED DESCRIPTION

Hereinafter, examples of the present disclosure will be described in detail with reference to the attached drawings so that the person of ordinary skill in the art may easily implement the present disclosure. As those skilled in the art would realize, the described embodiments may be modified in various different ways, all without departing from the spirit or scope of the present disclosure.

Embodiments described herein are example embodiments, and thus, the disclosure is not limited thereto.

In order to clarify the present disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the present disclosure is not limited to the illustrated sizes and thicknesses.

Throughout the specification, when it is described that a part is “connected (in contact with, coupled)” to another part, the part may be “directly connected” to the other element or “connected” to the other part through a third part. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

Further, in the specification, the phrase “on a plane” means when an object portion is viewed from above, and the phrase “on a cross-section” means when a cross-section taken by vertically cutting an object portion is viewed from the side.

Hereinafter, a semiconductor package and a manufacturing method of a semiconductor package of an embodiment will be described with reference to drawings.

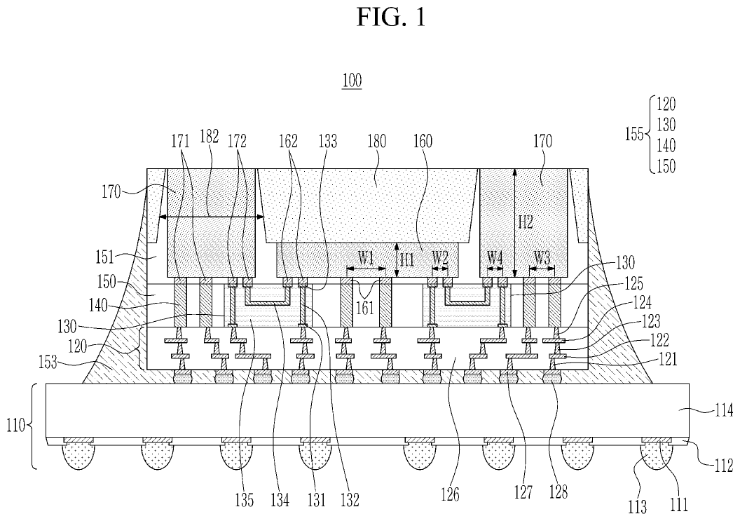

FIG. 1 is a cross-sectional view showing a semiconductor package 100 of an embodiment.

Referring to FIG. 1, the semiconductor package 100 may include a substrate 110, a composite interposer 155, a second molding material 151, an underfill material 153, a semiconductor structure 160, semiconductor stacking structures 170, and a heat dissipation structure 180.

In an embodiment, semiconductor package 100 may include a 2.5D semiconductor package. In an embodiment, the semiconductor package 100 may include a fan out wafer level package (FOWLP) or a fan out panel level package (FOPLP).

The substrate 110 may include a conductive pads 111, an insulation layer 112, external connection members 113, and a substrate base 114. The substrate 110 may include an Ajinomoto build-up film (ABF) substrate. In an embodiment, the substrate 110 may include a printed circuit board (PCB). In an embodiment, the substrate 110 may include an embedded trace substrate (ETS) having a coreless form in which a core layer is removed. The conductive pad 111 may electrically connect a wiring layer in the substrate base 114 to the external connection member 113. The insulation layer 112 may include a plurality of openings for soldering. The insulation layer 112 prevents the external connection members 113 from short-circuiting each other. The external connection member 113 may electrically connect the semiconductor package 100 to an external device.

In an embodiment, the conductive pads 111 may include at least one of copper, nickel, zinc, gold, silver, platinum, palladium, chromium, titanium and alloys thereof. In an embodiment, the insulation layer 112 may include a solder resist. In an embodiment, the external connection member 113 may include at least one of tin, silver, lead, nickel, copper, or an alloy thereof. In an embodiment, the substrate base 114 may include at least one of a thermosetting epoxy resin and a resin including a filler. In another embodiment, the substrate base 114 may include an Ajinomoto build-up film (ABF).

The composite interposer 155 may include a redistribution structure 120, bridge dies 130, conductive posts 140, and a first molding material 150.

The redistribution structure 120 may include a dielectric material layer 126, first redistribution vias 121, first redistribution lines 122, second redistribution vias 123, second redistribution lines 124, and third redistribution vias 125 in the dielectric material layer 126. In another embodiment, a redistribution structure may include fewer or greater numbers of redistribution lines and redistribution vias.

The dielectric material layer 126 protects and insulates the first redistribution vias 121, the first redistribution lines 122, the second redistribution vias 123, the second redistribution lines 124, and the third redistribution vias 125. Bridge dies 130, conductive posts 140, and a first molding material 150 may be disposed on the upper surface of the dielectric material layer 126. Connection pads 127 and connection members 128 may be disposed on the bottom surface of the dielectric material layer 126.

The first redistribution via 121 may be disposed between the first redistribution line 122 and the connection pad 127. The first redistribution via 121 may electrically connect the first redistribution line 122 to the connection pad 127 in a vertical direction. The first redistribution line 122 may be disposed between the first redistribution via 121 and the second redistribution via 123. The first redistribution line 122 may electrically connect the first redistribution via 121 and the second redistribution via 123 in a horizontal direction. The second redistribution via 123 may be disposed between the first redistribution line 122 and the second redistribution line 124. The second redistribution via 123 may electrically connect the second redistribution line 124 to the first redistribution line 122 in a vertical direction. The second redistribution line 124 may be disposed between the second redistribution via 123 and the third redistribution via 125. The second redistribution line 124 may electrically connect the second redistribution via 123 and the third redistribution via 125 in a horizontal direction. The third redistribution via 125 may be disposed between the second redistribution line 124 and the lower connection pad 131 of the bridge die 130, and between the second redistribution line 124 and the conductive post 140. The third redistribution via 125 may electrically connect the lower connection pad 131 of the bridge die 130 to the second redistribution line 124 and the conductive post 140 to the second redistribution line 124 in the vertical direction.

The connection pad 127 may be disposed between the first redistribution via 121 and the connection member 128. The connection pad 127 may electrically connect the first redistribution via 121 to the connection member 128. The connection member 128 may be disposed between the connection pad 127 and the substrate 110. The connection member 128 may electrically connect the connection pad 127 to the substrate 110.

The bridge dies 130 may be disposed on the redistribution structure 120. The bridge die 130 may electrically connect the redistribution structure 120 and the semiconductor stacking structure 170, the redistribution structure 120 and the semiconductor structure 180, and the semiconductor stacking structure 170 and the semiconductor structure 180. Therefore, the redistribution structure 120 and the semiconductor stacking structure 170, the redistribution structure 120 and the semiconductor structure 180, and the semiconductor stacking structure 170 and the semiconductor structure 180 may exchange signals with each other through the bridge die 130.

The bridge die 130 may include a bridge base 135, and lower connection pads 131, through silicon vias (TSV) 132, upper connection pads 133, and connection lines 134 in the bridge base 135. Side surfaces of the bridge die 130 may be molded in the first molding material 150.

The lower connection pad 131 may be disposed between the through silicon via 132 and the third redistribution via 125. The lower connection pad 131 may electrically connect the through silicon via 132 to the third redistribution via 125. The through silicon via 132 may be disposed between the lower connection pad 131 and the upper connection pad 133. The through silicon via 132 may electrically connect the upper connection pad 133 to the lower connection pad 131. The upper connection pad 133 may be disposed between the through silicon via 132 and the second connection terminal 162, between the through silicon via 132 and the fourth connection terminal 172, between the connection line 134 and the second connection terminal 162, and between the connection line 134 and the fourth connection terminal 172. The upper connection pad 133, in a vertical direction, may electrically connect the second connection terminal 162 to the through silicon via 132, the fourth connection terminal 172 to the through silicon via 132, the second connection terminal 162 to the connection line 134, and the fourth connection terminal 172 to the connection line 134. The connection line 134 may electrically connect the upper connection pads 133 in a horizontal direction.

In an embodiment, the bridge base 135 may include, for example, silicon. In an embodiment, through silicon via 132 may include at least one of tungsten, aluminum, copper and alloys thereof. The lower connection pad 131 and the upper connection pad 133 may each include at least one of copper, aluminum, silver, tin, gold, nickel, lead, titanium, and an alloy thereof. The connection line 134 may include at least one of copper, aluminum, silver, tin, gold, nickel, lead, titanium, tungsten and alloys thereof.

The through silicon via 132 included in the bridge die 130 may more quickly move data in a vertical direction, and the connection line 134 may more quickly move data in a horizontal direction.

Accordingly, the performance of the semiconductor package may be improved by reducing a power consumption in the semiconductor package. In addition, the normal pitch I/Os of the semiconductor stacking structure 170 and the semiconductor structure 180 are connected through the conductive post 140, the fine pitch I/Os of the semiconductor stacking structure 170 and the semiconductor structure 180 are connected through the bridge die 130, so that signals and power transmitted to the semiconductor stacking structure 170 and the semiconductor structure 180 may be transmitted more efficiently.

The conductive posts 140 may be disposed on the upper surface of the redistribution structure 120. The conductive post 140 may be disposed while penetrating the first molding material 150. The conductive post 140 electrically connect the third connection terminal 171 to the third redistribution via 125 of the redistribution structure 120, and the first connection terminal 161 to the third redistribution via 125 of the redistribution structure 120.

The first molding material 150 may mold the side surface of the bridge dies 130 and the side surfaces of the conductive posts 140 on the redistribution structure 120.

The semiconductor structure 160 may be disposed on the composite interposer 155. In an embodiment, the semiconductor structure 160 may include a logic die. In an embodiment, the semiconductor structure 160 may include an application specific integrated circuit (ASIC). In an embodiment, the semiconductor structure 160 may include a system on chip (SoC). In an embodiment, the semiconductor structure 160 may include at least one of a central processing unit (CPU) and a graphic processing unit (GPU).

The semiconductor structure 160 may include a first connection terminal 161 and a second connection terminal 162 on the bottom surface thereof. The first connection terminal 161 may be electrically connected to the conductive post 140. The second connection terminal 162 may be electrically connected to the upper connection pad 133. The first connection terminals 161 may correspond to the I/O with a normal pitch, and the second connection terminals 162 may correspond to the I/O with a fine pitch. An arrangement interval W1 of the neighboring first connection terminals among the first connection terminals 161 may be greater than an arrangement interval W2 of the neighboring second connection terminals among the second connection terminals 162.

The bottom surface and side surfaces of the semiconductor structure 160 may be surrounded by the second molding material 151. The heat dissipation structure 180 may be disposed on the upper surface of the semiconductor structure 160. The upper surface of the semiconductor structure 160 may directly contact the bottom surface of the heat dissipation structure 180.

The semiconductor stacking structures 170 may be disposed on the composite interposer 155. The semiconductor stacking structures 170 may be disposed side by side with the semiconductor structure 160. The semiconductor stacking structures 170 may be disposed around the semiconductor structure 160. In an embodiment, the semiconductor stacking structure 170 may include a high-bandwidth memory (HBM). The HBM is a dynamic random access memory (DRAM) of a high performance three-dimensional 3D stack. The HBM is manufactured by vertically stacking memory dies on a buffer chip to form a single memory stack by performing a hybrid bonding or using micro bumps. Accordingly, the height H2 of the semiconductor stacking structure (HBM) 170 in the vertical direction may be higher than the height H1 of the semiconductor structure (the logic die) 160.

The semiconductor stacking structure 170 may include a third connection terminal 171 and a fourth connection terminal 172 on the bottom surface thereof. The third connection terminal 171 may be electrically connected to the conductive post 140. The fourth connection terminal 172 may be electrically connected to the upper connection pad 133. The third connection terminals 171 may correspond to the I/O with a normal pitch, and the fourth connection terminals 172 may correspond to the I/O with a fine pitch. An arrangement interval W3 of the neighboring third connection terminals among the third connection terminals 171 may be greater than an arrangement interval W4 of the neighboring fourth connection terminals among the fourth connection terminals 172.

The semiconductor stacking structure 170 may be positioned within the through opening 182 of the heat dissipation structure. The upper surface of the semiconductor stacking structure 170 may be exposed externally through a through opening 182. The bottom surface and side surfaces of the semiconductor stacking structure 170 may be surrounded by a second molding material 151.

The heat dissipation structure 180 may be disposed on the semiconductor structure 160 and may include through openings 182. The bottom surface of the heat dissipation structure 180 may be in directly contact with the upper surface of the semiconductor structure 160. Another bottom surface of the heat dissipation structure 180 that is not in direct contact with the upper surface of the semiconductor structure 160 may be in contact with the second molding material 151. The semiconductor stacking structure 170 may be positioned within each through opening 182 of the through openings 182 of the heat dissipation structure 180. The space between the inner sidewall of the through opening 182 of the heat dissipation structure 180 and the semiconductor stacking structure 170 may be filled with the second molding material 151. The heat dissipation structure 180 may be provided on cover the entire upper surface of the semiconductor structure 160 and the second molding material 151 except for the upper surface of the semiconductor stacking structure 170 exposed through the through opening 182.

The heat dissipation structure 180 may include a heat sink. The heat sink may be referred to by terms such as heat slug or heat spread. In an embodiment, heat dissipation structure 180 may be formed using a carrier. In an embodiment, the heat dissipation structure 180 may include a silicon material having high thermal conductivity compared to the second molding material 151. In an embodiment, the heat dissipation structure 180 may include a conductive material having high thermal conductivity, such as copper or aluminum. As a result, by disposing the heat dissipation structure 180 on the semiconductor structure 160 having the height in the vertical direction that is relatively low compared to the semiconductor stacking structure 170, heat generated in the semiconductor structure 160 may be more efficiently discharged outside the semiconductor package 100. Therefore, according to embodiments, the thermal characteristic of the semiconductor package 100 may be improved, and when designing the semiconductor structure 160 and the semiconductor stacking structure 170, an allowable numerical range for the height in the vertical direction may be expanded.

The second molding material 151 may mold the semiconductor structure 160 and the plurality of semiconductor stacking structure 170 between the first molding material 150 and the heat dissipation structure 180.

The underfill material 153 may be disposed between the substrate 110 and the redistribution structure 120. The underfill material 153 may surround the connection pads 127 and the connection members 128 between the substrate 110 and the redistribution structure 120. The underfill material 153 may extend to at least a part of the side surface of the heat dissipation structure 180 via the bottom surface of the redistribution structure 120, the side surface of the redistribution structure 120, the side surface of the first molding material 150, and the side surface of the second molding material 151. In an embodiment, the underfill material 153 may include a nonconductive film (NCF) or a nonconductive paste (NCP). A stress generated in the semiconductor package 100 may be relieved by disposing the underfill material 153 between the substrate 110 and the redistribution structure 120. In addition, the underfill material 153 is extended to the side surface of the heat dissipation structure 180 so that the stress applied to the second molding material 151 may be dispersed toward the heat dissipation structure 180, thereby improving the reliability of the semiconductor package 100.

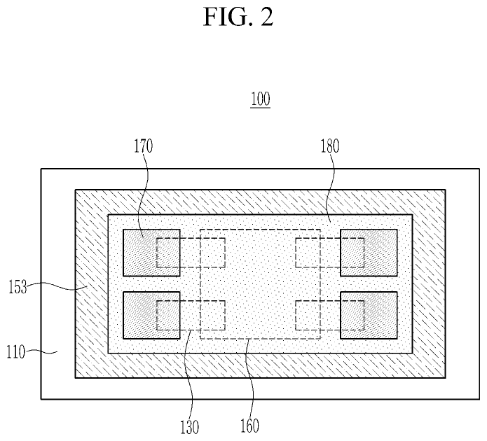

FIG. 2 is a top plan view showing an upper surface of a semiconductor package 100 of FIG. 1.

Referring to FIG. 2, when viewing the semiconductor package 100 in a plan view, the semiconductor stacking structures 170 may be disposed within the through openings 182 of the heat dissipation structure 180, and the underfill material 153 may be adjacent to and surround the heat dissipation structure 180. Since the semiconductor structure 160 is disposed on the bottom surface of the heat dissipation structure 180, the outer line of the semiconductor structure 160 is shown as a dotted line. The semiconductor stacking structures 170 may be disposed at a position spaced apart from the side surface of the semiconductor structure 160. Each semiconductor stacking structure among the semiconductor structure 160 and the semiconductor stacking structures 170 may be electrically connected by bridge dies 130. Since the bridge dies 130 are disposed below the bottom surface of the semiconductor structure 160 and the semiconductor stacking structures 170, the outline of the bridge dies 130 is shown as a dotted line.

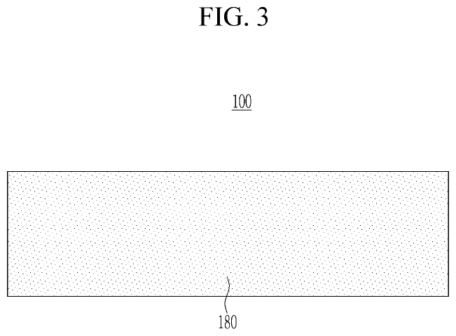

FIG. 3 to FIG. 19 are cross-sectional views showing a method of manufacturing a semiconductor package 100 of an embodiment.

FIG. 3 is a cross-sectional view showing a step of providing a carrier 180.

Referring to FIG. 3, the carrier 180 is provided. The carrier 180 may be used to manufacture the semiconductor package 100, but may function as a heat dissipation structure 180 in a final product. In an embodiment, the carrier 180 may include a silicon material having a thermal conductivity higher than a thermal conductivity of the second molding material 151. In an embodiment, the carrier 180 may include a conductive material having relatively high thermal conductivity, such as copper or aluminum.

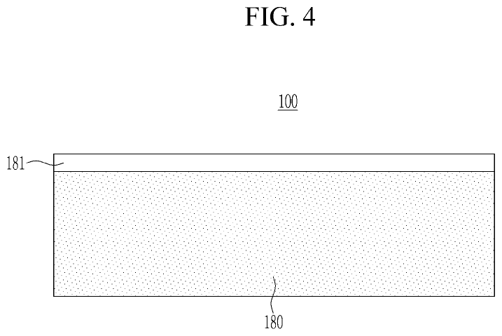

FIG. 4 is a cross-sectional view showing a step of forming a photoresist 181 on the first surface of the carrier 180.

Referring to FIG. 4, the photoresist 181 may be formed on the first surface of the carrier 180. In an embodiment, the photoresist 181 may be formed through a spin coating. In an embodiment, the photoresist 181 may include an organic polymer resin including a photosensitivity (photoactive) material. In another embodiment, the photoresist 181 may be formed through a sputtering process, physical vapor deposition (PVD) process, atomic layer deposition (ALD) process or chemical vapor deposition (CVD) process, or the like. However, embodiments are not limited thereto.

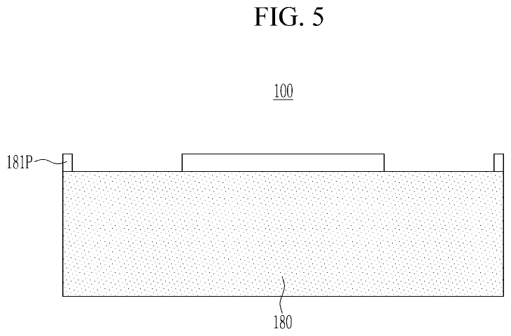

FIG. 5 is a cross-sectional view showing a step of forming a photoresist pattern 181P by exposing and developing the photoresist 181.

Referring to FIG. 5, the photoresist pattern 181P may be formed by exposing and developing the photoresist 181.

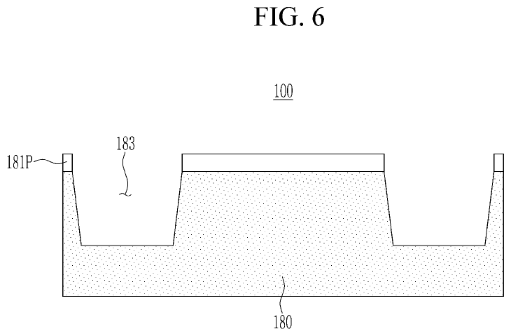

FIG. 6 is a cross-sectional view showing a step of forming cavities 183 in the carrier 180.

Referring to FIG. 6, the first surface of the carrier 180 is etched using the photoresist pattern 181P as an etching mask, and the cavities 183 may be formed in the carrier 180. The width of the cavity 183 in a horizontal direction may increase from the bottom to the top in a vertical direction.

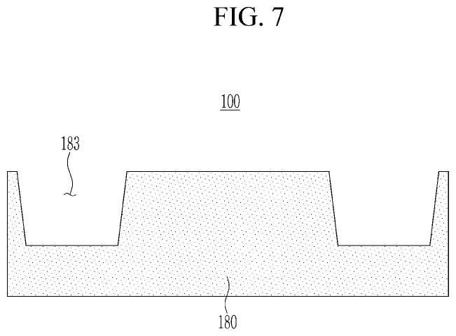

FIG. 7 is a cross-sectional view showing a step of removing the photoresist pattern 181P from the first surface of the carrier 180.

Referring to FIG. 7, the photoresist pattern 181P may be removed from the first surface of the carrier 180. In an embodiment, the photoresist pattern 181P may be removed by, for example, at least one of etching, ashing and strip.

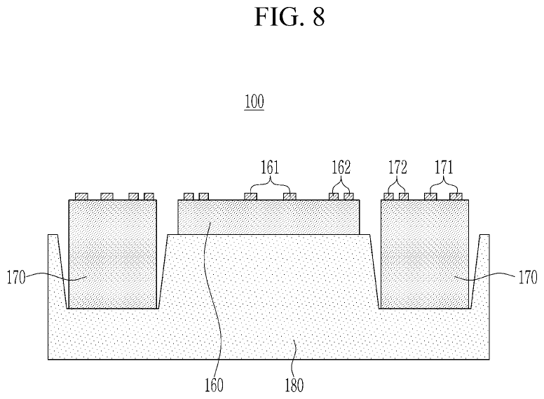

FIG. 8 is a cross-sectional view showing steps of attaching a semiconductor structure 160 on the carrier 180 and attaching a semiconductor stacking structure 170 on the cavity 183 of the carrier 180.

Referring to FIG. 8, an adhesive layer may be formed by performing an oxidation process on the surface of the carrier 180. The adhesive layer may be formed through a thermal oxidation, a plasma oxidation, a physical vapor deposition (PVD) process, an atomic layer deposition (ALD) process or a chemical vapor deposition (CVD) process. Then, by performing an oxide bonding, the upper surface of the semiconductor structure 160 may be attached to the adhesive layer of the first surface of the carrier 180, and the upper surfaces of the semiconductor stacking structures 170 may be attached to the adhesive layer of the cavities 183 of the carrier 180. The first connection terminal 161 and the second connection terminal 162 of the semiconductor structure 160, and the third connection terminal 171 and the fourth connection terminal 172 of the semiconductor stacking structure 170 may be positioned on the opposite side from the carrier 180.

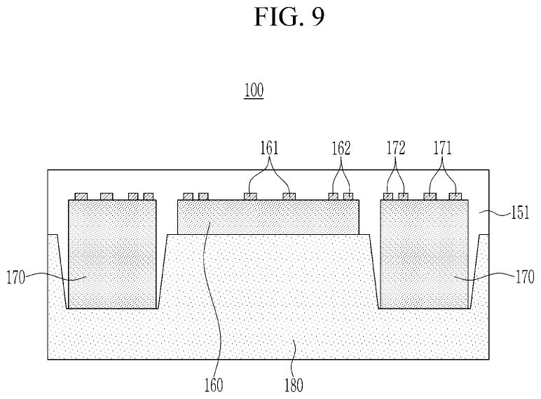

FIG. 9 is a cross-sectional view showing a step of molding the semiconductor structure 160 and the semiconductor stacking structures 170 with the second molding material 151 on the carrier 180.

Referring to FIG. 9, on the carrier 180, the semiconductor structure 160 and the semiconductor stacking structures 170 may be molded with the second molding material 151. As an embodiment, the molding process with the second molding material 151 may include a compression molding or a transfer molding process. In an embodiment, the second molding material 151 may include an epoxy molding compound (EMC).

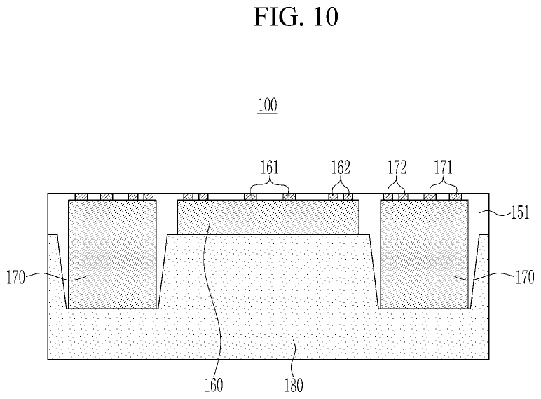

FIG. 10 is a cross-sectional view showing a step of planarizing the second molding material 151.

Referring to FIG. 10, after the molding process, in order to level the bottom surface of the second molding material 151, a chemical mechanical polishing (CMP) may be performed to planarize the bottom surface of the second molding material 151. After performing the planarization process, the bottom surface of the first connection terminals 161 and the second connection terminals 162 of the semiconductor structure 160, and the bottom surface of the third connection terminals 171 and the fourth connection terminals 172 of the semiconductor stacking structure 170 may be exposed.

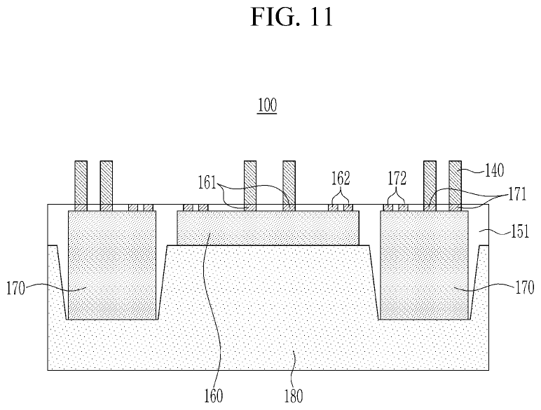

FIG. 11 is a cross-sectional view showing a step of forming conductive posts 140 on the first connection terminal 161 of the semiconductor structure 160, and the third connection terminal 171 of the semiconductor stacking structure 170.

Referring to FIG. 11, the conductive posts 140 may be formed in a vertical direction on the first connection terminal 161 of the semiconductor structure 160 and the third connection terminal 171 of the semiconductor stacking structure 170. In an embodiment, the conductive posts 140 may be formed by performing a sputtering process. In another embodiment, conductive posts 140 may be formed by performing an electrolytic plating process after forming a seed metal layer. In an embodiment, the conductive posts 140 may include at least one of copper, aluminum, tungsten, nickel, gold, silver, chromium, antimony, tin, titanium and alloys thereof.

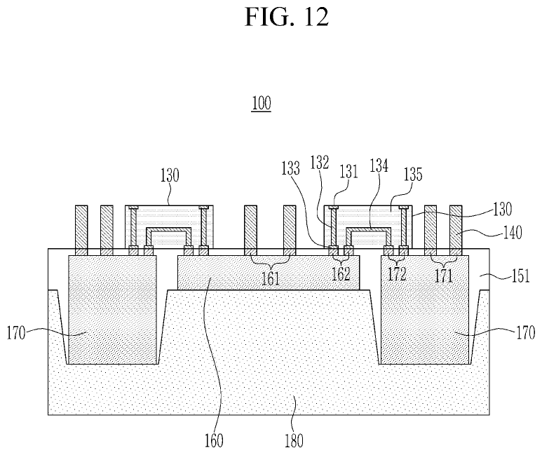

FIG. 12 is a cross-sectional view showing a step of mounting bridge dies 130 on the second connection terminal 162 of the semiconductor structure 160 and the fourth connection terminal 172 of the semiconductor stacking structure 170.

Referring to FIG. 12, the bridge dies 130 may be connected to the second connection terminal 162 of the semiconductor structure 160 and the fourth connection terminal 172 of the semiconductor stacking structure 170. The bridge die 130 may be disposed so that an active surface faces the semiconductor structure 160 and the semiconductor stacking structure 170. In an embodiment, to electrically connect the bridge dies 130 to the second connection terminal 162 of the semiconductor structure 160, and the fourth connection terminal 172 of the semiconductor stacking structure 170, a copper to copper bonding, a solder reflow, or a bonding using a connection member may be performed between the upper connection pads 133 of the bridge dies 130 and the second connection terminal 162 of the semiconductor structure 160, and between the upper connection pads 133 of the bridge dies 130 and the fourth connection terminal 172 of the semiconductor stacking structure 170.

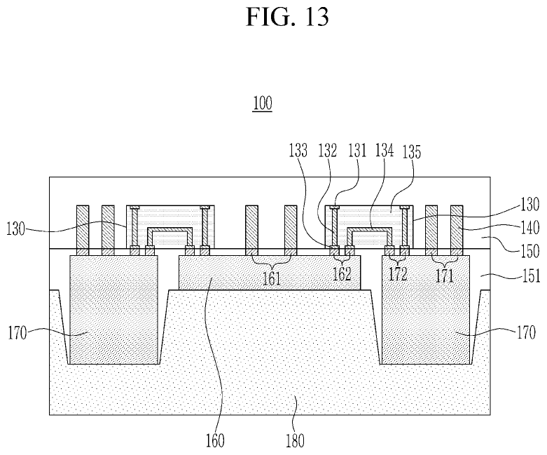

FIG. 13 is a cross-sectional view showing a step of molding the bridge dies 130 and the conductive posts 140 with a first molding material 150 on the second molding material 151.

Referring to FIG. 13, on the second molding material 151, the bridge dies 130 and the conductive posts 140 may be molded with the first molding material 150. As an embodiment, the molding process with the first molding material 150 may include a compression molding or a transfer molding process. In an embodiment, the first molding material 150 may include an epoxy molding compound (EMC).

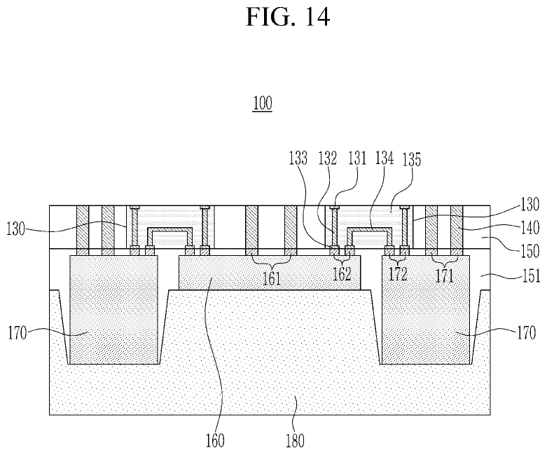

FIG. 14 is a cross-sectional view showing a step of planarizing the first molding material 150.

Referring to FIG. 14, after the molding process, to level the bottom surface of the first molding material 150, the chemical mechanical polishing (CMP) may be performed to planarize the bottom surface of the first molding material 150. After performing the planarization process, the bottom surface of the bridge die 130 and the bottom surface of the conductive posts 140 may be exposed.

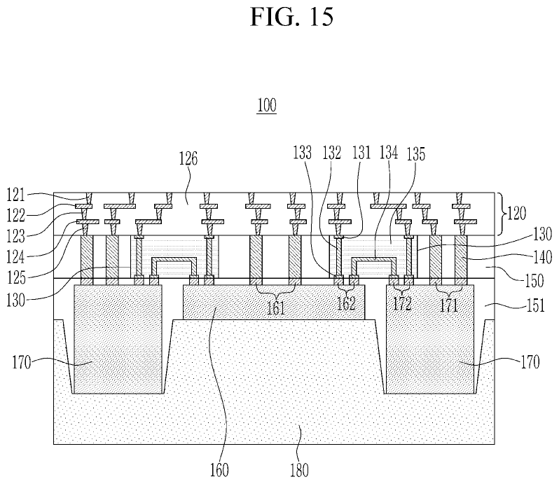

FIG. 15 is a cross-sectional view showing a step of forming a redistribution structure 120 on the first molding material 150.

Referring to FIG. 15, the dielectric material layer 126 may be formed on the first molding material 150. In an embodiment, the dielectric material layer 126 may include a photosensitive dielectric (e.g., photo imageable dielectric (PID)) used in the redistribution process. The PID is a material that may form a fine pattern by applying a photolithography process. As an embodiment, the PID may include a polyimide-based photoactive polymer, a novolac-based photoactive polymer, polybenzoxazole, a silicon-based polymer, an acrylate-based polymer, or an epoxy-based polymer. In another embodiment, the dielectric material layer 126 may be formed of an inorganic dielectric material such as silicon nitride, silicon oxide, or the like. In an embodiment, the dielectric material layer 126 may be formed by a chemical vapor deposition (CVD) process, an atomic layer deposition (ALD) process, or a plasma enhanced chemical vapor deposition (PECVD) process.

After forming the dielectric material layer 126, via holes may be formed by selectively etching the dielectric material layer 126, and third redistribution vias 125 may be formed by filling the via holes with a conducting material.

Then, a dielectric material layer 126 may be additionally deposited on the third redistribution vias 125 and the dielectric material layer 126, the additionally deposited dielectric material layer 126 may be selectively etched to form openings, and the openings may be filled with a conducting material to form second redistribution lines 124.

Next, a dielectric material layer 126 may be additionally deposited on the second redistribution lines 124 and the dielectric material layer 126, the additionally deposited dielectric material layer 126 may be selectively etched to form via holes, and the via holes may be filled with a conducting material to form the second redistribution vias 123.

Next, a dielectric material layer 126 may be additionally deposited on the second redistribution vias 123 and the dielectric material layer 126, the additionally deposited dielectric material layer 126 may be selectively etched to form openings, and first redistribution lines 122 may be formed by filling the openings with a conducting material.

Next, a dielectric material layer 126 may be additionally deposited on the first redistribution lines 122 and the dielectric material layer 126, the additionally deposited dielectric material layer 126 may be selectively etched to form via holes, and the via holes may be filled with a conducting material to form first redistribution vias 121.

In an embodiment, the first redistribution vias 121, the first redistribution lines 122, the second redistribution vias 123, the second redistribution lines 124, and the third redistribution vias 125 may include at least one of copper, aluminum, tungsten, nickel, gold, tin, titanium and alloys thereof. In an embodiment, the first redistribution vias 121, the first redistribution lines 122, the second redistribution vias 123, the second redistribution lines 124, and the third redistribution vias 125 may be formed by performing a sputtering process. In another embodiment, the first redistribution vias 121, the first redistribution lines 122, the second redistribution vias 123, the second redistribution lines 124, and the third redistribution vias 125 may be formed by performing an electrolytic plating process after forming a seed metal layer.

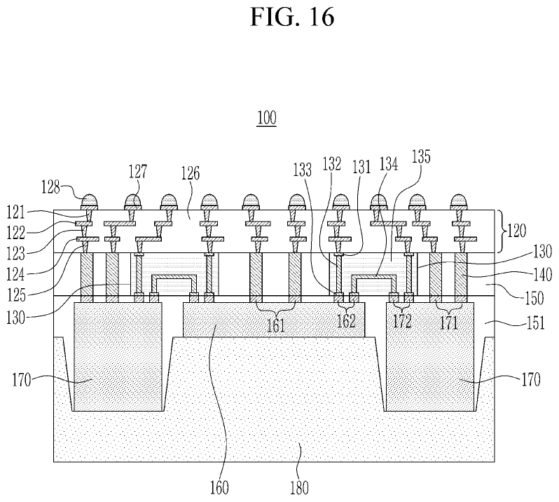

FIG. 16 is a cross-sectional view showing the steps of forming connection pads 127 and connection members 128 on the bottom surface of the redistribution structure 120.

Referring to FIG. 16, the connection pads 127 may be formed on the bottom surface of the redistribution structure 120, and the connection members 128 may be formed on each connection pad 127. In an embodiment, the connection pad 127 may include at least one of copper, nickel, zinc, gold, silver, platinum, palladium, chromium, titanium and alloys thereof. In an embodiment, the connection member 128 may include at least one of tin, silver, lead, nickel, copper, or an alloy thereof. In an embodiment, the connection pad 127 may be formed by performing a sputtering process, or an electrolytic plating process after forming a seed metal layer. In an embodiment, the connection member 128 may be formed by performing a reflow process.

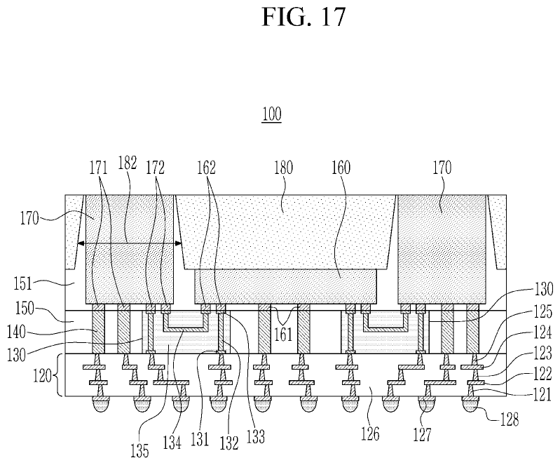

FIG. 17 is a cross-sectional view showing a step of planarizing the carrier 180.

Referring to FIG. 17, in order to level the second surface opposite to the first surface of the carrier 180, a planarization process may be performed to form a heat dissipation structure 180. In an embodiment, the planarization process may be performed by a chemical mechanical polishing (CMP), or a mechanical grinding process. After performing the planarization process, the upper surface of the semiconductor stacking structures 170 is exposed from the heat dissipation structure 180, and the upper surface of the semiconductor stacking structure 170 may have the same level as the level of the upper surface of the heat dissipation structure 180. Also, after performing the planarization process, the cavity 183 of the carrier 180 may become a through opening 182 of the heat dissipation structure 180. Thus, the carrier 180 is not used only within the process of manufacturing the semiconductor package 100, but may function as the heat dissipation structure 180 in the final product. Therefore, the process of removing the carrier from the semiconductor package 100 may be omitted. The width of the through opening 182 may decrease from the lower portion of the through opening 182 to the upper portion of the through opening 182.

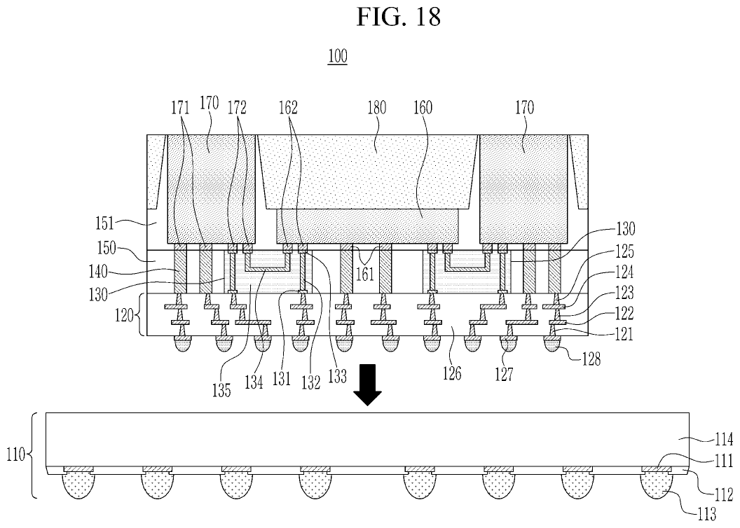

FIG. 18 is a cross-sectional view showing the step of attaching the redistribution structure 120 on the substrate 110 through a connection members 128.

Referring to FIG. 18, the redistribution structure 120 may be attached to the substrate 110.

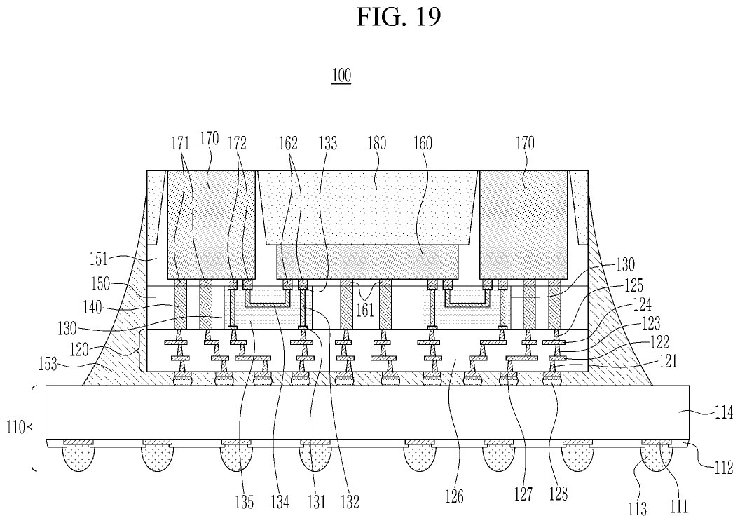

FIG. 19 is a cross-sectional view showing a step of forming an underfill material between the redistribution structure 120 and the substrate 110.

Referring to FIG. 19, an underfill material 153 may be formed between the redistribution structure 120 and the substrate 110 to surround the connection pads 127 and the connection members 128. In this way, by disposing the underfill material 153, stress between the redistribution structure 120 and the substrate 110 may be relieved. In addition, the underfill material 153 may be formed to extend to at least a part of the side surface of the heat dissipation structure 180 via the bottom surface of the redistribution structure 120, the side surface of the redistribution structure 120, the side surface of the first molding material 150, and the side surface of the second molding material 151. Accordingly, it is possible to prevent cracks from occurring at the interface between the second molding material 151 and the first molding material 152 and at the interface between the first molding material 152 and the redistribution structure 120. In an embodiment, the underfill material 153 may include, for example, a nonconductive film (NCF) or a nonconductive paste (NCP).

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a redistribution structure;
a semiconductor structure on the redistribution structure;
a plurality of semiconductor stacking structures on the redistribution structure, the plurality of semiconductor stacking structures being adjacent to the semiconductor structure, and a height of each of the plurality of semiconductor stacking structures being greater than a height of the semiconductor structure; and
a heat dissipation structure on the semiconductor structure, the heat dissipation structure comprising a plurality of through openings,
wherein each semiconductor stacking structure among the plurality of semiconductor stacking structures is positioned within a corresponding through opening among the plurality of through openings, and
wherein an upper surface of each of the plurality of semiconductor stacking structures is exposed through the corresponding through opening.

2. The semiconductor package of claim 1, wherein the upper surface of each of the plurality of semiconductor structures directly contacts a bottom surface of the heat dissipation structure.

3. The semiconductor package of claim 1, wherein a level of the upper surface of each of the plurality of semiconductor stacking structures is equal to a level of an upper surface of the heat dissipation structure.

4. The semiconductor package of claim 1, wherein the heat dissipation structure comprises silicon.

5. The semiconductor package of claim 1, wherein the heat dissipation structure comprises a conductive material.

6. The semiconductor package of claim 1, wherein a width of each through opening among the plurality of through openings in a horizontal direction decreases upwards in a vertical direction.

7. A semiconductor package comprising:
a substrate;
a redistribution structure on the substrate;
a plurality of conductive posts on the redistribution structure;
a bridge die on the redistribution structure;
a first molding material molding the plurality of conductive posts and the bridge die on the redistribution structure;
a semiconductor structure on the first molding material;
a plurality of semiconductor stacking structures on the first molding material, the plurality of semiconductor stacking structures being adjacent to the semiconductor structure, and a height of each of the plurality of semiconductor stacking structures being greater than a height of the semiconductor structure;
a heat dissipation structure on the semiconductor structure, the heat dissipation structure comprising a plurality of through openings, and each of the plurality of semiconductor stacking structures being positioned within a corresponding through opening of the plurality of through openings, and an upper surface of each of the plurality of semiconductor stacking structures being exposed through the corresponding through opening; and
a second molding material, that molds the semiconductor structure and the plurality of semiconductor stacking structures, between the first molding material and the heat dissipation structure.

8. The semiconductor package of claim 7, wherein the heat dissipation structure is on the second molding material and the semiconductor structure.

9. The semiconductor package of claim 7, wherein the plurality of semiconductor stacking structures comprise a high-bandwidth memory (HBM).

10. The semiconductor package of claim 9, wherein the HBM comprises a buffer chip and a plurality of memory dies on the buffer chip.

11. The semiconductor package of claim 7, wherein the semiconductor structure comprises an application specific integrated circuit (ASIC).

12. The semiconductor package of claim 7, further comprising:
a plurality of connection members between the substrate and the redistribution structure.

13. The semiconductor package of claim 12, further comprising:
an underfill material surrounding the plurality of connection members.

14. The semiconductor package of claim 13, wherein the underfill material comprises a nonconductive film (NCF) or a nonconductive paste (NCP).

15. The semiconductor package of claim 13, wherein the underfill material extends to a side of the heat dissipation structure through a side surface of the redistribution structure, ae side surface of the first molding material, and a side surface of the second molding material.

16. The semiconductor package of claim 7, wherein the bridge die comprises a plurality of bridge dies, and
wherein each of the plurality of bridge dies electrically connects a corresponding semiconductor stacking structure of the plurality of semiconductor stacking structures and the semiconductor structure.

17. The semiconductor package of claim 7, wherein each of the plurality of conductive posts electrically connects the redistribution structure and the semiconductor structure, or the redistribution structure and each of the plurality of semiconductor stacking structures.

18. A manufacturing method of a semiconductor package comprising:
forming a plurality of cavities on a first surface of a carrier;
forming a plurality of semiconductor stacking structures and a semiconductor structure on the carrier, each semiconductor stacking structure among the plurality of semiconductor stacking structures being formed within a corresponding cavity among the plurality of cavities, the semiconductor structure being formed on the first surface of the carrier between the plurality of cavities, and a height of each of the plurality of semiconductor stacking structures being higher than a height of the semiconductor structure;
molding the plurality of semiconductor stacking structures and the semiconductor structure with a molding material on the carrier;
forming a redistribution structure on the molding material; and
planarizing a second surface of the carrier opposite to the first surface of the carrier to expose an upper surface of each of the plurality of semiconductor stacking structures.

19. The manufacturing method of the semiconductor package of claim 18, wherein, in the forming of the plurality of semiconductor stacking structures and the semiconductor structure on the carrier, the plurality of semiconductor stacking structures and the semiconductor structure are formed on the carrier by oxide bonding.

20. The manufacturing method of the semiconductor package of claim 18, wherein the planarizing of the second surface opposite to the first surface of the carrier is performed by a chemical mechanical polishing process.
